(19) United States
(12) Patent Application Publication
(10) Pub. No.: US 2026/0305463 A1
(43) Pub. Date: Oct. 1, 2026

(54) METHOD FOR MANUFACTURING SEMICONDUCTOR DEVICE, AND CURABLE RESIN COMPOSITION

(71) Applicant: Resonac Corporation, Minato-ku, Tokyo (JP)

(72) Inventors: Shintaro NAGAYAMA, Tokyo (JP); Chikashi AOYAGI, Tokyo (JP); Ryo SUGANO, Tokyo (JP)

(21) Appl. No.: 19/479,348

(22) PCT Filed: Sep. 29, 2023
(86) PCT No.: PCT/JP2023/035692

§ 371 Date: Oct. 28, 2025

(51) Int. Cl. H10W 80/00; C09D 179/08

(52) U.S. Cl. CPC H10W 80/334; C09D 179/085

(57) ABSTRACT

A method for manufacturing a semiconductor device, including: forming a preliminary thermocompression bonded body by thermocompression-bonding a second circuit member having a second insulating film to a first circuit member having a second insulating film by a preliminary thermocompression head; and forming a bonded body in which the first insulating film and the second insulating film are bonded by pressurizing the preliminary thermocompression bonded body while heating. At least one of the first insulating film or the second insulating film is an organic insulating film. A plurality of the second circuit members are sequentially thermocompression-bonded to the first circuit member by the preliminary thermocompression head while maintaining a temperature of the preliminary thermocompression head within a range of a predetermined minimum temperature or more and a preliminary thermocompression temperature or less.

### TECHNICAL FIELD

The present disclosure relates to a method for manufacturing a semiconductor device, and a curable resin composition for hybrid bonding used therein.

### BACKGROUND ART

In three-dimensional packaging of semiconductor chips, application of a hybrid bonding technique in which an insulating film is bonded together with bonding of electrodes has been studied for refinement of wiring. It has also been proposed to form an insulating film for the hybrid bonding technique using a resin material such as polyimide (Patent Literature 1).

On the other hand, it is known that a composition containing a maleimide compound and an allyl compound is thermally cured by an addition reaction including an ene reaction and a Diels-Alder reaction or by radical polymerization (Non Patent Literature 1).

### CITATION LIST

### Patent Literature

Patent Literature 1: International Publication No. WO 2020/085183

### Non Patent Literature

Non Patent Literature 1: Handbook of Thermoset Plastics, Third Edition, 2014, p. 459-510

### SUMMARY OF INVENTION

### Technical Problem

The present disclosure relates to efficiently manufacturing a large number of semiconductor devices having a semiconductor substrate bonded to another circuit member by hybrid bonding.

### Solution to Problem

The present disclosure includes the following.

[1]

A method for manufacturing a semiconductor device, comprising:
preparing a first circuit member comprising a first substrate, a first electrode, and a first insulating film, the first electrode and the first insulating film being provided on the first substrate, the first insulating film forming an opening, and the first electrode being provided in the opening;
preparing a second circuit member comprising a second substrate, a second electrode, and a second insulating film, the second electrode and the second insulating film being provided on the second substrate, the second insulating film forming an opening, and the second electrode being provided in the opening;
disposing the first circuit member on a stage in an orientation such that the first substrate is positioned on the stage side;
holding the second circuit member on a preliminary thermocompression head in an orientation such that the second substrate is in contact with the preliminary thermocompression head;
thermocompression-bonding the second circuit member held on the preliminary thermocompression head to the first circuit member on the stage in an orientation such that the first electrode and the second electrode face each other, by the preliminary thermocompression head heated such that a maximum temperature of the preliminary thermocompression head is a preliminary thermocompression temperature, the preliminary thermocompression temperature being 250° C. or less, thereby forming a preliminary thermocompression bonded body having the first circuit member and the second circuit member; and
forming a bonded body comprising the first circuit member and the second circuit member, the first insulating film and the second insulating film being bonded together and the first electrode and the second electrode being bonded together, by pressurizing the preliminary thermocompression bonded body while heating to a bonding temperature equal to or higher than the preliminary thermocompression temperature,
wherein
at least one of the first substrate or the second substrate is a semiconductor substrate having a circuit surface,
when the first substrate is a semiconductor substrate having a circuit surface, the first electrode and the first insulating film are provided on the circuit surface, and when the second substrate is a semiconductor substrate having a circuit surface, the second electrode and the second insulating film are provided on the circuit surface,
at least one of the first insulating film or the second insulating film is an organic insulating film,
a plurality of the second circuit members are sequentially thermocompression-bonded to the first circuit member by the preliminary thermocompression head while maintaining a temperature of the preliminary thermocompression head within a range of a predetermined minimum temperature or more and the preliminary thermocompression temperature or less, and
the minimum temperature is a temperature of 70° C. or more and the preliminary thermocompression temperature or less.
   [2]

The method according to [1], wherein the preliminary thermocompression temperature is 80° C. or more and 250° C. or less.

[3]

The method according to [1], wherein the preliminary thermocompression temperature is 100° C. or more and 250° C. or less.

[4]

The method according to [1], wherein the preliminary thermocompression temperature is 100° C. or more and 220° C. or less.

[5]

The method according to any one of [1] to [4], wherein a difference between the preliminary thermocompression temperature and the minimum temperature is 20° C. or less.

[6]

The method according to any one of [1] to [4], wherein a difference between the preliminary thermocompression temperature and the minimum temperature is 10° C. or less.

[7]

The method according to any one of [1] to [6], wherein the bonding temperature is 200° C. or more and 350° C. or less.

[8]

The method according to any one of [1] to [7], wherein the organic insulating film includes a resin comprising an imide group.

[9]

The method according to [8], wherein the organic insulating film includes a cured product of a curable resin composition containing a maleimide compound having a maleimide group and an allyl compound having an allyl group.

[10]

The method according to [8], wherein the resin comprising an imide group is a polyimide resin, a polyamide-imide resin, a bismaleimide resin, or a combination thereof.

[11]

The method according to [8], wherein the resin comprising an imide group is a resin having a constitutional unit comprising an imide group and a polysiloxane bonded to the constitutional unit.

[12]

The method according to any one of [1] to [7], wherein the organic insulating film includes a cured product of a curable resin composition containing an epoxy resin.

[13]

The method according to any one of [1] to [7], wherein the organic insulating film includes a polybenzoxazole resin.

[14]

The method according to any one of [1] to [7], wherein the organic insulating film includes a benzocyclobutene resin.

[15]

A curable resin composition, containing a maleimide compound having a maleimide group and an allyl compound having an allyl group, for use in forming an organic insulating film in the method according to any one of [1] to [7].

### Advantageous Effects of Invention

It is possible to efficiently manufacture a large number of semiconductor devices having a semiconductor substrate bonded to another circuit member by hybrid bonding.

### BRIEF DESCRIPTION OF DRAWINGS

FIG. 1 is a process diagram showing an example of a method for manufacturing a semiconductor device.

FIG. 2 is a process diagram showing an example of the method for manufacturing a semiconductor device.

FIG. 3 is a process diagram showing an example of the method for manufacturing a semiconductor device.

FIG. 4 is a process diagram showing an example of the method for manufacturing a semiconductor device.

FIG. 5 is a process diagram showing an example of the method for manufacturing a semiconductor device.

FIG. 6 is a process diagram showing an example of the method for manufacturing a semiconductor device.

FIG. 7 is a graph showing an example of a temperature profile of a preliminary thermocompression head in a step of forming a preliminary thermocompression bonded body.

FIG. 8 is a graph showing an example of a temperature profile of the preliminary thermocompression head in the step of forming the preliminary thermocompression bonded body.

### DESCRIPTION OF EMBODIMENTS

The present invention is not limited to the following examples.

### Method for Manufacturing Semiconductor Device

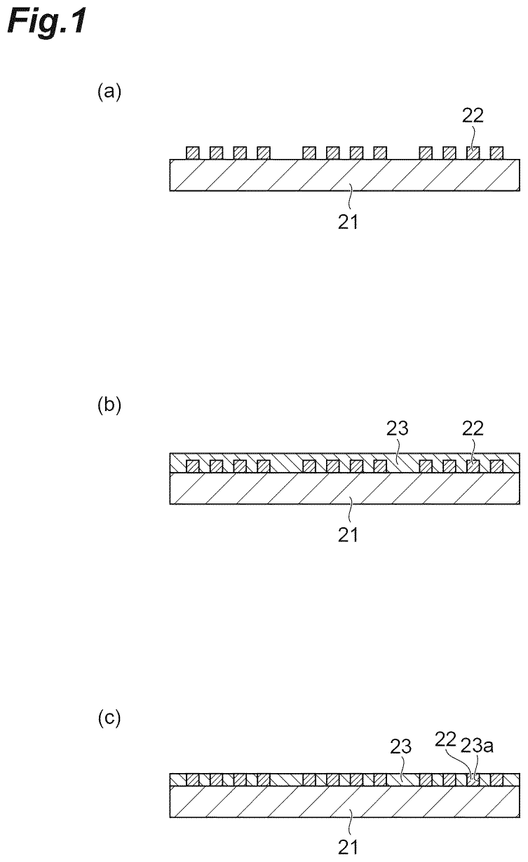

FIGS. 1, 2, 3, 4, 5, and 6 are process diagrams showing an example of a method for manufacturing a semiconductor device. The method shown in FIGS. 1 to 6 includes preparing a first circuit member 10 having a first substrate 11, a first electrode 12, and a first insulating film 13; preparing a second circuit member 20A having a second substrate 21A, a second electrode 22, and a second insulating film 23; disposing the first circuit member 10 on a stage 60 in an orientation such that the first substrate 11 is positioned on the stage 60 side; holding the second circuit member 20A on a preliminary thermocompression head 65 in an orientation such that the second substrate 21A is in contact with the preliminary thermocompression head 65; thermocompression-bonding the second circuit member 20A held on the preliminary thermocompression head 65 to the first circuit member 10 on the stage 60 in an orientation such that the first electrode 12 and the second electrode 22 face each other, by the preliminary thermocompression head 65 heated to a maximum temperature that becomes a predetermined preliminary thermocompression temperature, thereby forming a preliminary thermocompression bonded body 30 having the first circuit member 10 and the second circuit member 20A; and forming a bonded body 35 having the first circuit member 10 and the second circuit member 20A by pressurizing the preliminary thermocompression bonded body 30 while heating to a bonding temperature equal to or higher than the preliminary thermocompression temperature. By dividing the first circuit member 10 of the bonded body 35 on a dicing tape 80, a semiconductor device 35A, which is a bonded body of a singulated first circuit member 10A and the second circuit member 20A, is formed.

The first insulating film 13 and the second insulating film 23 can be an organic insulating film or an inorganic insulating film applicable to hybrid bonding. At least one of the first insulating film 13 or the second insulating film 23 is an organic insulating film. Details of the organic insulating film will be described later. At least one of the first substrate 11A or the second substrate 21A is a semiconductor substrate (for example, a silicon substrate) having a circuit surface on which an integrated circuit is provided. The first circuit member 10A or the second circuit member 20A having the first substrate 11A or the second substrate 21A that is not a semiconductor substrate may be, for example, an organic interposer.

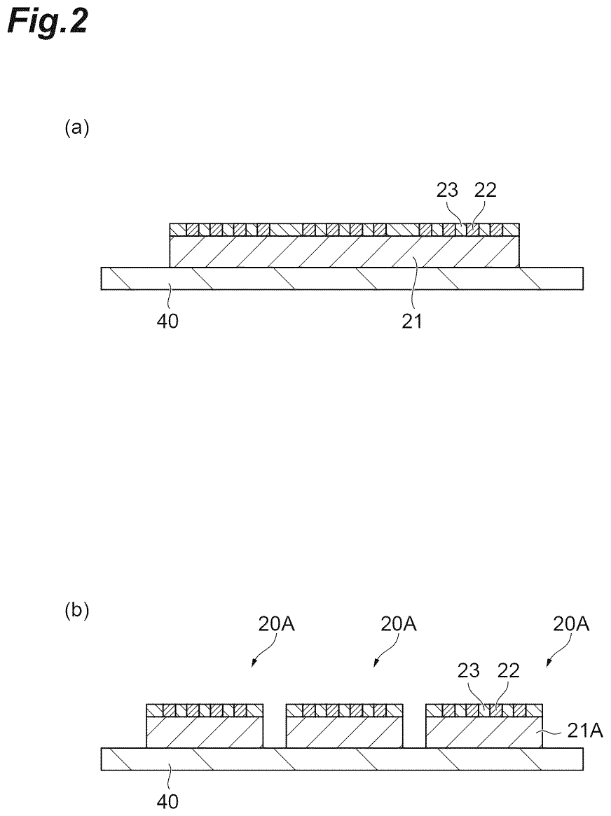

The second circuit member 20A is prepared by a method including, for example, providing a plurality of second electrodes 22 on one principal surface of an original substrate 21 including portions corresponding to a plurality of second substrates 21A as shown in (a) of FIG. 1; forming a second insulating film 23 covering the second electrodes 22 on the original substrate 21 as shown in (b) of FIG. 1; removing a part of the second insulating film 23 from the side opposite to the original substrate 21 to expose the second electrodes 22 as shown in (c) of FIG. 1; and forming a plurality of second circuit members 20A having singulated second substrates 21A by dividing the original substrate 21 together with the second insulating film 23 on a dicing tape 40 as shown in FIG. 2. The original substrate 21 may be a semiconductor wafer, and the second substrate 21A may be a singulated semiconductor substrate (chip). The method for removing a part of the second insulating film 23 may be, for example, chemical mechanical polishing (CMP). In the second circuit member 20A, the second insulating film 23 forms a plurality of openings 23a which are through-holes exposing the second substrate 21A, and the first electrode 12 is provided in the openings 23a. A flat surface may be formed by the second electrode 22 and the second insulating film 23. A protrusion or a recess may be formed at the position of the second electrode 22. When the second substrate 21A is a semiconductor substrate having a circuit surface, the second electrode 22 and the second insulating film 23 are usually provided on the circuit surface. The method for dividing the original substrate 21 can be normal dicing.

The original substrate 21 (particularly a semiconductor wafer) may be disk-shaped. In that case, the diameter of the original substrate 21 may be 150 mm or more and 300 mm or less. The thickness of the original substrate 21 may be 40 μm or more and 1000 μm or less.

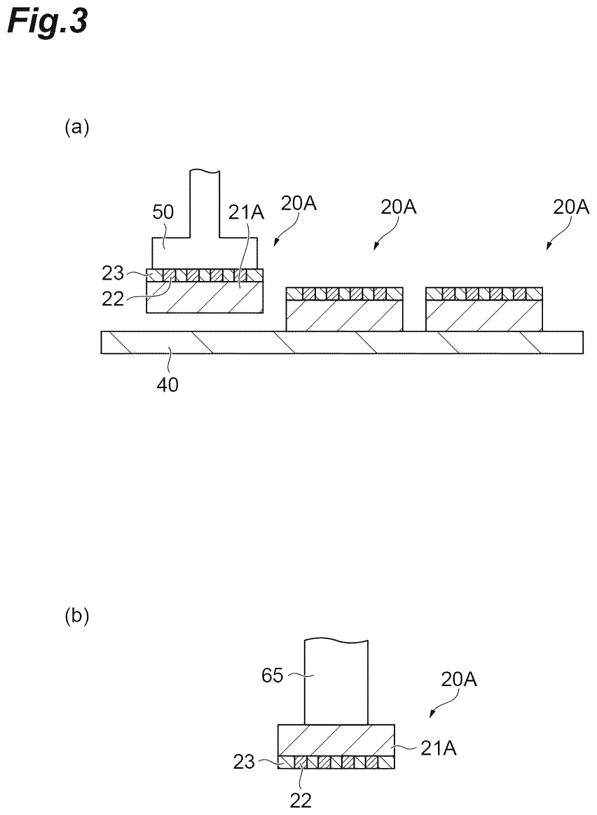

The plurality of second circuit members 20A formed on the dicing tape 40 are sequentially picked up by a pickup tool 50, as shown in (a) of FIG. 3. The second circuit member 20A is suctioned by the pickup tool 50 in an orientation such that the second electrode 22 and the second insulating film 23 are positioned on the pickup tool 50 side. The picked-up second circuit member 20A is transferred from the pickup tool 50 to a preliminary thermocompression head 65, as shown in (b) of FIG. 3. The preliminary thermocompression head 65 holds the second circuit member 20A in an orientation such that the second substrate 21A is positioned on the preliminary thermocompression head 65 side. The second circuit member 20A may be suctioned by the preliminary thermocompression head 65. The preliminary thermocompression head 65 may be, for example, a head of a normal flip-chip bonder.

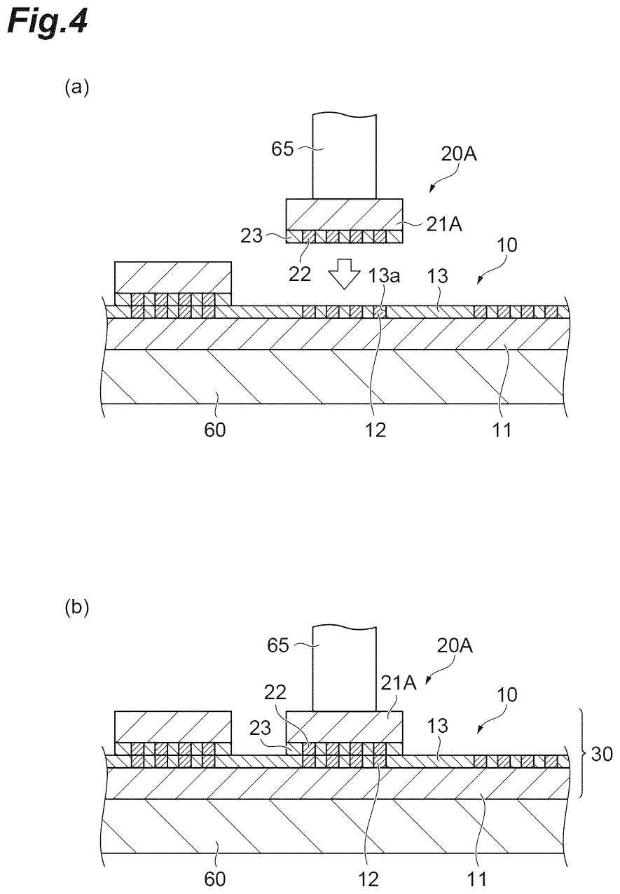

As shown in (a) of FIG. 4, the second circuit member 20A held by the preliminary thermocompression head 65 is aligned directly above the first circuit member 10A disposed on the stage 60 such that the first electrode 12 and the second electrode 22 to be bonded face each other.

The first circuit member 10 includes portions corresponding to a plurality of circuit members after being singulated. Therefore, the first electrodes 12 and the first insulating film 13 constituting a plurality of circuit members are provided on a single first substrate 11. The first insulating film 13 forms a plurality of openings 13a which are through-holes exposing the first substrate 11, and the first electrode 12 is provided in the openings 13a. The first circuit member 10 can be prepared by a method similar to the method illustrated in FIG. 1, except that the first substrate 11 is not divided. The first substrate 11 of the prepared first circuit member 10 may be a semiconductor wafer having a circuit surface. In that case, the first electrode 12 and the first insulating film 13 are usually provided on the circuit surface. In this example, the first circuit member before being singulated and the singulated second circuit member are bonded. According to the method of the present disclosure, singulated circuit members may be bonded to each other, or circuit members before being singulated may be bonded to each other.

The shapes of the first electrode 12 and the second electrode 22 are not particularly limited, but some or all of these electrodes are arranged such that the first electrode 12 and the second electrode 22 face and are bonded to each other. The width of the first electrode 12 and the second electrode 22 may be, for example, 1 μm or more or 100 μm or more, and may be 300 μm or less or 30 μm or less. The width here means the maximum width of each electrode in a direction parallel to the principal surface (circuit surface) of the first substrate 11 or the second substrate 21A. The spacing between adjacent first electrodes 12 and the spacing between adjacent second electrodes 22 may be, for example, 1 μm or more or 100 μm or more, and may be 300 μm or less or 30 μm or less. The height of the first electrode 12 and the second electrode 22 may be, for example, 1 μm or more or 10 μm or more, and may be 100 μm or less or 10 μm or less. The height of the first electrode 12 may be the same as or different from the thickness of the first insulating film 13. The height of the second electrode 22 may be the same as or different from the thickness of the second insulating film 23.

The first electrode 12 and the second electrode 22 are formed from a conductive material containing a metal such as copper. The first electrode 12 containing a metal can be formed by a normal method such as a plating method.

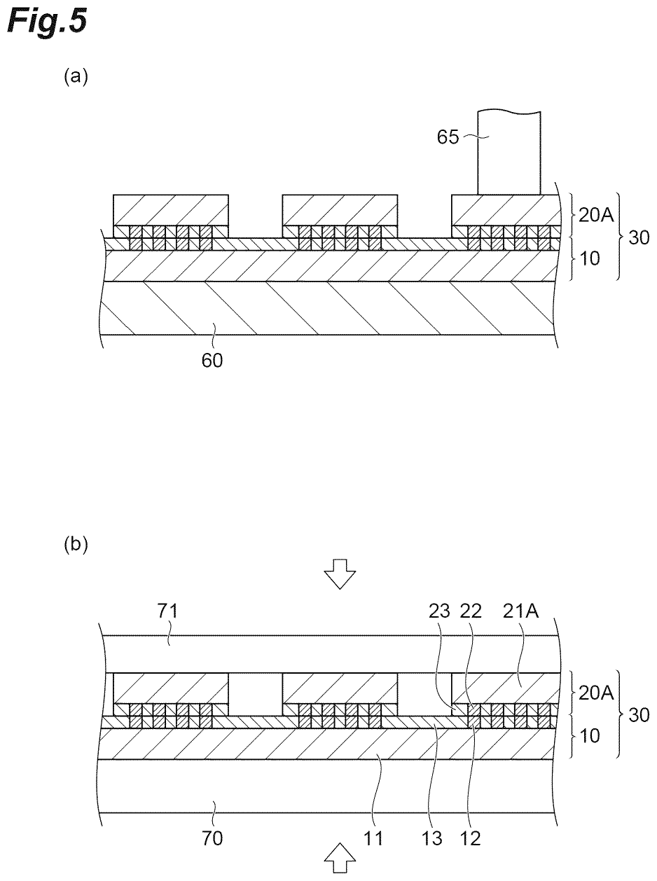

Subsequently, as shown in (b) of FIG. 4, the second circuit member 20A is thermocompression-bonded to the first circuit member 10 by the preliminary thermocompression head 65. By this thermocompression bonding, a preliminary thermocompression bonded body 30 in which the first circuit member 10 and the second circuit member 20A are preliminarily bonded is formed. During the thermocompression bonding, the second circuit member 20A is heated by heat conduction from the heated preliminary thermocompression head 65 and is pressed by the preliminary thermocompression head 65. As shown in FIGS. 4 and 5, a plurality of second circuit members 20A are sequentially thermocompression-bonded to the first circuit member 10 by one preliminary thermocompression head. At the stage of the preliminary thermocompression bonded body 30, the first insulating film 13 and the second insulating film 23 are mainly bonded to some extent.

Before the second circuit member 20A is thermocompression-bonded to the first circuit member 10, the first insulating film 13, the second insulating film 23, or both may be irradiated with ultraviolet light.

While the plurality of second circuit members 20A are sequentially thermocompression-bonded, that is, while the preliminary thermocompression head 65 repeats holding the second circuit member 20A, aligning the second circuit member 20A on the first circuit member 10, and then thermocompression-bonding the second circuit member 20A to the first circuit member 10, the temperature of the preliminary thermocompression head 65 is maintained within a range of a predetermined minimum temperature or more and the preliminary thermocompression temperature or less. The temperature of the stage 60 may also be similarly maintained within a range of the predetermined minimum temperature or more and the preliminary thermocompression temperature or less.

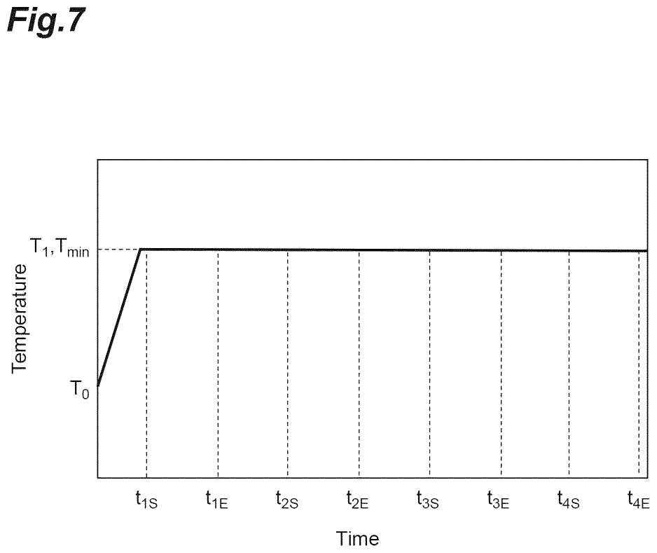

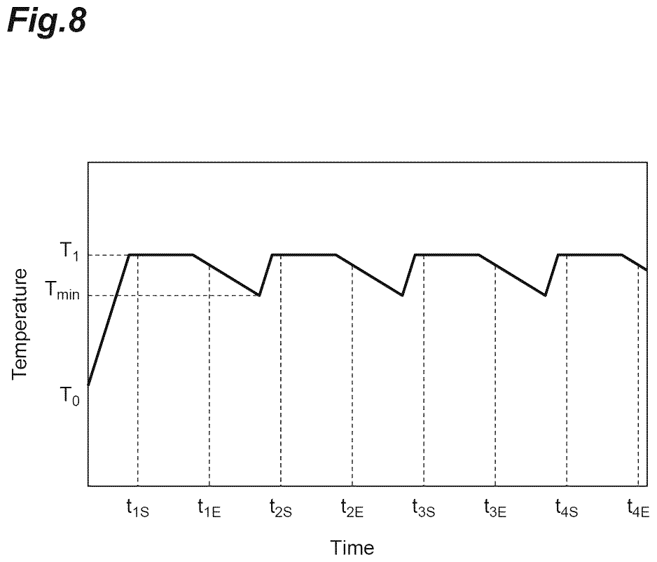

FIGS. 7 and 8 are graphs showing examples of the temperature profile of the preliminary thermocompression head 65 while a plurality of second circuit members 20A are sequentially thermocompression-bonded to the first circuit member 10. FIGS. 7 and 8 show the relationship between the temperature of the preliminary thermocompression head 65 and time. During the period from time t_{1S} to time t_{1E}, from time t_{2S} to time t_{2E}, from time t_{3S} to time t_{3E}, and from time t_{4S} to time t_{4E}, the second circuit member 20A is pressed against the first circuit member 10 by the preliminary thermocompression head 65. First, the temperature of the preliminary thermocompression head 65 is raised from an initial temperature To t₀ a predetermined preliminary thermocompression temperature T₁. In the examples of FIGS. 7 and 8, the temperature of the preliminary thermocompression head 65 reaches the preliminary thermocompression temperature T₁ before time t_{1S} when the thermocompression bonding of the first second circuit member 20A is started. The temperature of the preliminary thermocompression head 65 may reach the preliminary thermocompression temperature T₁ at any point during the thermocompression bonding of the second circuit member 20A, that is, between time t_{1S} and time t_{1E}. The preliminary thermocompression temperature T₁ is the maximum temperature of the preliminary thermocompression head 65 while the holding and thermocompression bonding of the plurality of second circuit members 20A are repeated. At the time when the first second circuit member 20A is held by the preliminary thermocompression head 65, the temperature of the preliminary thermocompression head 65 may be an initial temperature T₀ lower than the minimum temperature Tₘᵢₙ, or may be any temperature between the temperature T₀ and the preliminary thermocompression temperature T₁.

In the case of the example of FIG. 7, after reaching the preliminary thermocompression temperature T₁, the temperature of the preliminary thermocompression head 65 is maintained at the preliminary thermocompression temperature T₁ while the holding and thermocompression bonding of the plurality of second circuit members 20A are repeated. That is, the preliminary thermocompression temperature T₁ is equal to the minimum temperature Tₘᵢₙ. Note that even in this case, the temperature of the preliminary thermocompression head 65 may fluctuate slightly around the intended preliminary thermocompression temperature T₁ due to variations in the state of the apparatus, etc. For example, the temperature of the preliminary thermocompression head 65 may be maintained within a range of the preliminary thermocompression temperature T₁±2° C.

In the case of the example of FIG. 8, after reaching the preliminary thermocompression temperature T₁, the temperature of the preliminary thermocompression head 65 is maintained within a range of the minimum temperature Tₘᵢₙ or more and the preliminary thermocompression temperature T₁ or less while repeating the holding and thermocompression bonding of the plurality of second circuit members 20A. In the case of the example of FIG. 8, the temperature of the preliminary thermocompression head 65 starts to decrease from the preliminary thermocompression temperature T₁ at some point during the thermocompression bonding of one second circuit member 20A (for example, between time t_{1S} and time TIE), and reaches the minimum temperature Tₘᵢₙ after the thermocompression bonding of one second circuit member 20A is completed. The preliminary thermocompression head 65 holds the next second circuit member 20A to be thermocompression-bonded at any point before or after the temperature of the preliminary thermocompression head 65 reaches the minimum temperature Tₘᵢₙ.

When the temperature of the preliminary thermocompression head 65 is maintained at a high temperature of the minimum temperature Tₘᵢₙ or more, the time required for heating and cooling the preliminary thermocompression head 65 can be shortened. When the process time is shortened, the thermal history that the first circuit member 10 receives while a large number of second circuit members 20A are thermocompression-bonded to one first circuit member 10 is reduced. When the thermal history that the first circuit member 10 receives is small, deterioration due to oxidation of the first electrode 12, etc., can be suppressed. Since the second insulating film 23 applied to hybrid bonding tends to maintain low fluidity even at high temperatures, even if the second circuit member 20A is held by the preliminary thermocompression head 65 maintained at a high temperature, it is less susceptible to the influence of temperature. The preliminary thermocompression temperature T₁ may be, for example, 80° C. or more, 90° C. or more, 100° C. or more, 110° C. or more, 120° C. or more, or 130° C. or more, and may be 250° C. or less, 240° C. or less, 230° C. or less, 220° C. or less, 210° C. or less, 200° C. or less, 190° C. or less, 180° C. or less, 170° C. or less, 160° C. or less, 150° C. or less, or 140° C. or less. The minimum temperature Tₘᵢₙ is usually a temperature of 70° C. or more and the preliminary thermocompression temperature T₁ or less. The minimum temperature Tₘᵢₙ may be 80° C. or more, and may be 250° C. or less.

When the difference between the preliminary thermocompression temperature T₁ and the minimum temperature Tₘᵢₙ is small, the time required for heating and cooling the preliminary thermocompression head 65 can be shortened. From such a viewpoint, the difference between the preliminary thermocompression temperature T₁ and the minimum temperature Tₘᵢₙ may be 20° C. or less, or 10° C. or less.

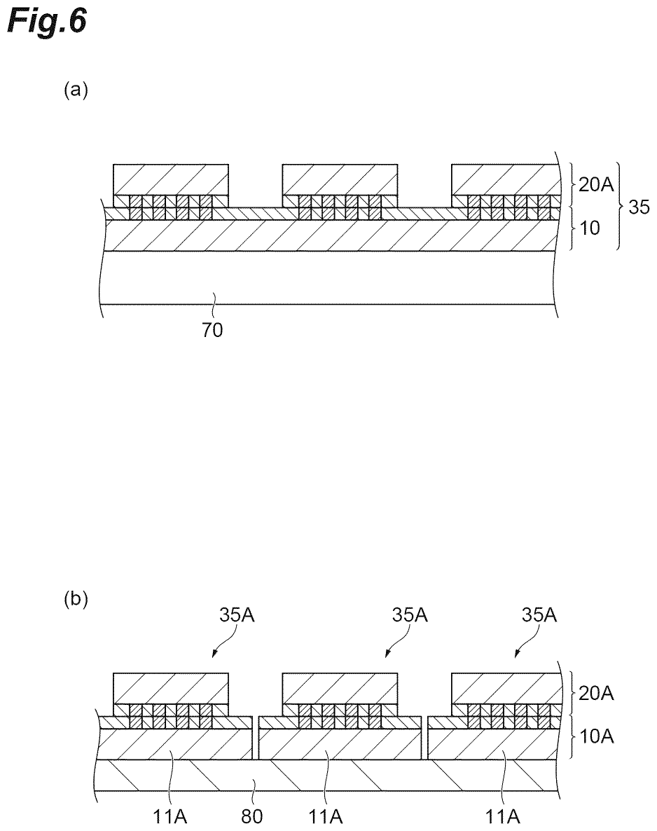

After the preliminary thermocompression bonded body 30 having one first circuit member 10 and a plurality of second circuit members 20A is formed, as shown in (b) of FIG. 5, the preliminary thermocompression bonded body 30 is pressurized while being heated to a bonding temperature equal to or higher than the preliminary thermocompression temperature T₁. In the case of the example of FIG. 5, the preliminary thermocompression bonded body 30 is disposed on a stage 70, and the plurality of second circuit members 20A are collectively pressurized against the first circuit member 10 by a pressing member 71. The preliminary thermocompression bonded body 30 is heated to the bonding temperature by the stage 70, the pressing member 71, or both. By this heating and pressurization, a bonded body 35 having one first circuit member 10 and a plurality of second circuit members 20A, shown in (a) of FIG. 6, is formed. By the heating and pressurization at the bonding temperature, the first electrode 12 and the second electrode 22 are mainly bonded by material bonding, and the first insulating film 13 and the second insulating film 23 can be more strongly bonded.

The bonding temperature can be a temperature at which the first electrode 12 and the second electrode 22 are electrically connected by material bonding, and is usually a temperature equal to or higher than the preliminary thermocompression temperature T₁. For example, the bonding temperature may be 200° C. or more and 350° C. or less. The pressure for forming the bonded body 35 may be 1.0 MPa or more and 5.0 MPa or less. The time for heating and pressurization for forming the bonded body 35 may be, for example, 10 seconds or more and 2 hours or less. The method of heating and pressurization for forming the bonded body 35 is not limited to hot pressing by a pressing member, and may be, for example, heating in a pressurized atmosphere.

As shown in (b) of FIG. 6, the first circuit member 10 of the formed bonded body 35 is singulated into a plurality of first circuit members 10A on a dicing tape 80. As a result, a plurality of semiconductor devices 35A (bonded bodies) having the singulated first circuit member 10A and the second circuit member 20A are formed. As a dividing method for singulating the first circuit member 10, a normal dicing method can be adopted.

### Organic Insulating Film

The first insulating film 13, the second insulating film 23, or both can be an organic insulating film that can be bonded to another insulating film by heating and pressurization.

The organic insulating film may include a resin containing an imide group. For example, an organic insulating film including a cured product of a curable resin composition (hereinafter also referred to as “curable maleimide resin composition”) containing a maleimide compound having a maleimide group and an allyl compound having an allyl group includes a resin containing an imide group derived from the maleimide compound. The organic insulating film including the cured product of the curable maleimide resin composition can be favorably bonded to another insulating film by heating and pressurization. On the surface of the organic insulating film including the cured product of the curable maleimide resin composition, many maleimide groups, allyl groups, or functional groups derived therefrom may be present. Therefore, the organic insulating film can exhibit good bondability without necessarily requiring an activation treatment such as a plasma treatment. In addition, it may be possible to adjust the polishing rate of the organic insulating film based on the crosslinking density in the cured product. Both the first insulating film 13 and the second insulating film 23 may be organic insulating films including the cured product of the curable maleimide resin composition.

The maleimide compound is a compound having one or more maleimide groups. From the viewpoint of heat resistance of the cured product and reduction of the coefficient of thermal expansion, the curable maleimide resin composition may include a maleimide compound having two or more maleimide groups.

The maleimide compound may have an imide group containing a nitrogen atom directly bonded to a cyclic group (for example, an aromatic group). For example, the maleimide compound in the curable maleimide resin composition may include a compound represented by the following formula (Ia) or (Ib):

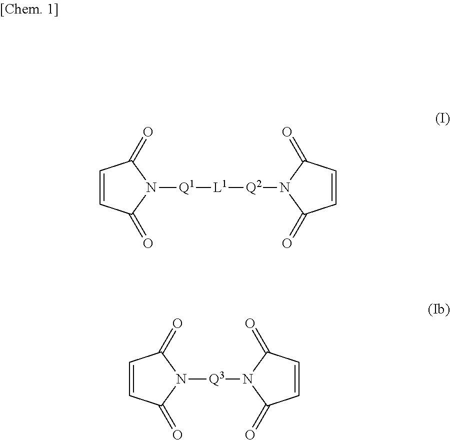

In formula (Ia), Q¹ and Q² each independently represent a cyclic group which may have a substituent, and L¹ represents a divalent organic group or a single bond. Q¹ and Q² may each independently be an aromatic group (for example, a phenylene group). L¹ may be a group including one or more cyclic groups (excluding a maleimide group) which may have a substituent, selected from a monocyclic ring, a condensed ring, a non-condensed bridged ring, and a spiro ring, a linear alkylene group which may have a substituent (for example, a methylene group, a propane-1,3-diyl group), a propane-2,2-diyl group which may have a substituent, or a single bond. L¹ may have two or more cyclic groups and a single bond or a divalent organic group (for example, a methylene group which may have a substituent, a propane-2,2-diyl group which may have a substituent) that links the two or more cyclic groups. L¹ may further have a methylene group that links the cyclic group and Q¹ or Q². The cyclic group in L¹ may be substituted with, for example, a methyl group or a maleimide group. L¹ may have a cyclic group resulting from removing one or more hydrogen atoms from benzene, 2,3-dihydro-1H-indene, or succinimide.

In formula (Ib), Q³ represents a cyclic group which may have a substituent. Q³ may be an aromatic group (for example, a phenylene group). The cyclic group in Q³ may be substituted with, for example, a methyl group or a maleimide group.

Specific examples of the maleimide compound include compounds represented by the following formula 11, 12, 13, or 14. In these formulas, n represents an integer of 1 or more.

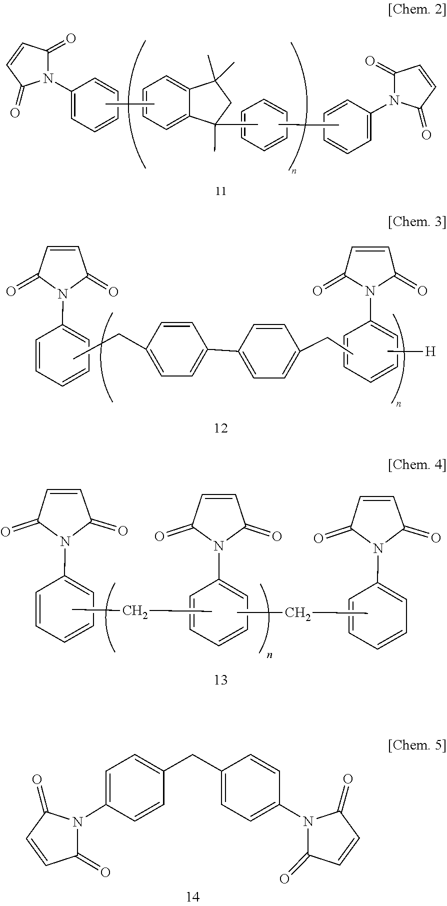

Examples of commercially available maleimide compounds include NE-X-9470S (trade name, DIC), MIR-3000-70MT (trade name, Nippon Kayaku), BMI-2300 (trade name, Daiwa Kasei Kogyo), BMI-5100 (trade name, Daiwa Kasei Kogyo), BMI-80 (trade name, Daiwa Kasei Kogyo), BMI (trade name, Daiwa Kasei Kogyo), and SFR-2300MR-T (trade name, Resonac).

The allyl compound is a compound having one or more allyl groups (2-propenyl group, —CH₂CH═CH₂). From the viewpoint of heat resistance of the cured product and reduction of the coefficient of thermal expansion, the curable maleimide resin composition may include an allyl compound having two or more allyl groups.

The allyl compound may include a compound having a cyclic group and an allyl group or an allyloxy group directly bonded to the cyclic group. For example, the allyl compound in the curable maleimide resin composition may include a compound represented by the following formula (IIa), (IIb), (IIc), or (IId):

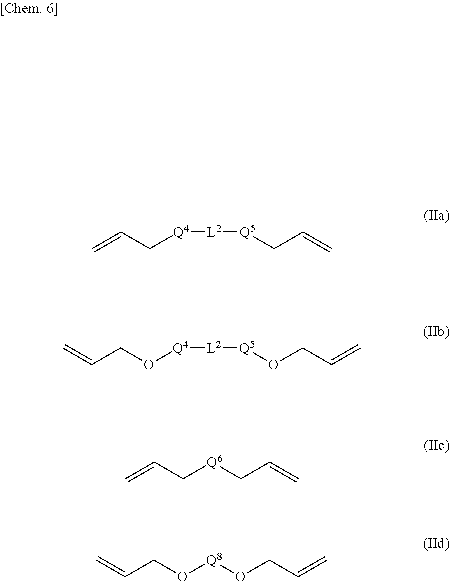

In formulas (IIa) and (IIb), Q⁴ and Q5 each independently represent a cyclic group which may have a substituent, and L² represents a divalent organic group or a single bond. Q⁴ and Q⁵ may each independently be a group resulting from removing one or more hydrogen atoms from benzene, isocyanuric acid, or nadimide. L² may be a group including one or more cyclic groups (excluding a maleimide group) which may have a substituent, selected from a monocyclic ring, a condensed ring, a non-condensed bridged ring, and a spiro ring, a linear alkylene group which may have a substituent (for example, a methylene group, a propane-1,3-diyl group), a propane-2,2-diyl group which may have a substituent, or a single bond. L² may have two or more cyclic groups and a single bond or a divalent organic group (for example, a methylene group which may have a substituent, a propane-2,2-diyl group which may have a substituent) that links the two or more cyclic groups. L² may further have a methylene group that links the cyclic group and Q⁴ or Q⁵. The cyclic group in L² may be substituted with a substituent selected from, for example, a methyl group, a hydroxy group, and an allyl group. L² may have a phenylene group which may have a substituent.

In formulas (IIc) and (IId), Q⁶ represents a cyclic group which may have a substituent. Q⁶ may be an aromatic group (for example, a phenylene group), or a group resulting from removing one or more hydrogen atoms from isocyanuric acid. The cyclic group in Q³ may be substituted with, for example, a methyl group or an allyl group.

Specific examples of the allyl compound include compounds represented by the following formula 21, 22, 23, 24, 25, 26, 27, 28, or 29. In these formulas, n represents an integer of 1 or more.

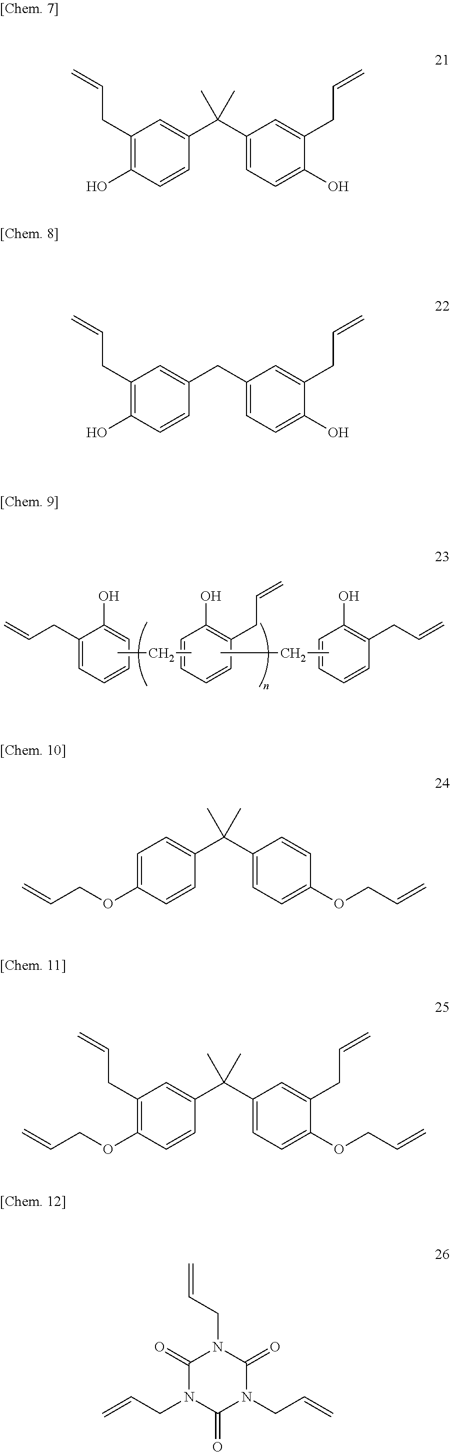

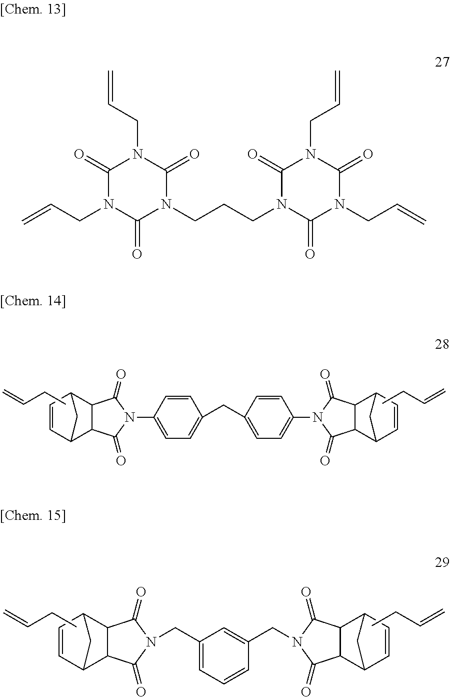

Examples of commercially available allyl compounds include DABPA (trade name, Kanto Chemical), DA-BPF (trade name, Yokkaichi Gosei), LVA01 (trade name, Gunei Chemical Industry), BPA-AE (trade name, Konishi Chemical Industry), BANI-X (trade name, Maruzen Petrochemical), BANI-M (trade name, Maruzen Petrochemical), FATC-809 (trade name, Gunei Chemical Industry), FATC-809AP (trade name, Gunei Chemical Industry), DAIC (trade name, Shikoku Chemicals Corporation), and DD-1 (trade name, Shikoku Chemicals Corporation).

The content of the allyl compound may be 10 mass % or more and 70 mass % or less, based on the total amount of the maleimide compound and the allyl compound. The content of the allyl compound may be 15 mass % or more, 20 mass % or more, 25 mass % or more, or 30 mass % or more, and may be 65 mass % or less, 60 mass % or less, or 55 mass % or less, based on the total amount of the maleimide compound and the allyl compound.

The curable maleimide resin composition may further include a component that initiates or promotes the reaction of the maleimide compound and the allyl compound.

The curable maleimide resin composition may further include a component that reduces the dielectric tangent of the cured product (hereinafter referred to as “dielectric tangent modifier”). The dielectric tangent modifier includes, for example, an aromatic compound represented by the following formula (IIIa), (IIIb), or (IIIc):

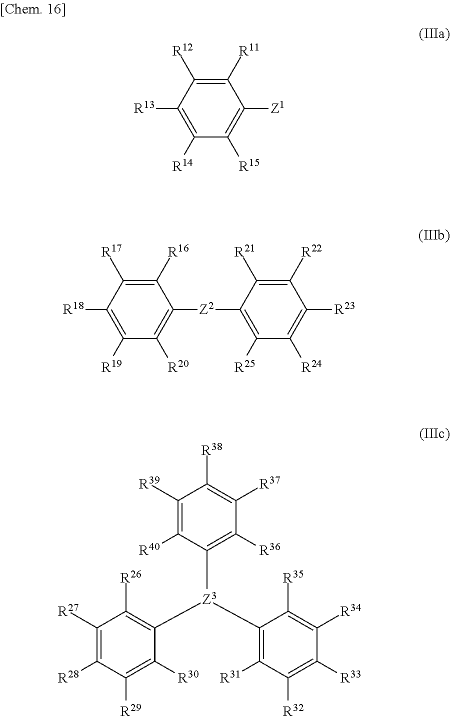

In formula (IIIa), R¹¹, R¹⁴, and R¹⁵ each independently represent a hydrogen atom, a methyl group, or a t-butyl group, R¹² and R¹³ each independently represent a hydrogen atom, a hydroxy group, or an organic group having 1 to 30 carbon atoms, and Z¹ represents an organic group having 7 to 80 carbon atoms containing at least one heteroatom selected from the group consisting of sulfur, phosphorus, oxygen, and nitrogen, or an organic group having 2 to 15 carbon atoms containing a carbonyl group.

In formula (IIIb), R¹⁶, R¹⁹, R²⁰, R²¹, R²², and R²⁵ each independently represent a hydrogen atom, a methyl group, or a t-butyl group, R¹⁷, R¹⁸, R²³, and R²⁴ each independently represent a hydrogen atom, a hydroxy group, or an organic group having 1 to 30 carbon atoms, and Z² represents a divalent organic group having 1 to 50 carbon atoms containing at least one heteroatom selected from the group consisting of sulfur, phosphorus, oxygen, and nitrogen, or a divalent organic group having 1 to 75 carbon atoms.

In formula (IIIc), R²⁶, R²⁹, R³⁰, R³¹, R³⁴, R³⁵, R³⁶, R³⁷, and R⁴⁰ each independently represent a hydrogen atom, a methyl group, or a t-butyl group, R²⁷, R²⁸, R³², R³³, R³⁸, and R³⁹ each independently represent a hydrogen atom, a hydroxy group, or an organic group having 1 to 30 carbon atoms, and Z³ represents a trivalent organic group having 1 to 50 carbon atoms containing at least one heteroatom selected from the group consisting of sulfur, phosphorus, oxygen, and nitrogen, or a trivalent organic group having 1 to 50 carbon atoms.

The content of the dielectric tangent modifier may be 1 mass % or more and 50 mass % or less based on the total amount of the maleimide compound and the allyl compound. The content of the dielectric tangent modifier may be 2 mass % or more or 5 mass % or more, and may be 50 mass % or less or 40 mass % or less, based on the total amount of the maleimide compound and the allyl compound.

The curable maleimide resin composition may further include a solvent that dissolves or disperses the maleimide compound and the allyl compound. Examples of the solvent include γ-butyrolactone, cyclohexanone, cyclopentanone, mesitylene, N,N-dimethylformamide, propylene glycol monomethyl ether acetate, and ethyl lactate.

The curable maleimide resin composition may further include an adhesion promoter. The adhesion promoter may include, for example, a silane coupling agent, an aluminum-based adhesion promoter, or a combination thereof.

Examples of the silane coupling agent include γ-aminopropyldimethoxysilane, N-(β-aminoethyl)-γ-aminopropylmethyldimethoxysilane, γ-glycidoxypropylmethyldimethoxysilane, γ-mercaptopropylmethyldimethoxysilane, 3-methacryloxypropyldimethoxymethylsilane, 3-methacryloxypropyltrimethoxysilane, dimethoxymethyl-3-piperidinopropylsilane, diethoxy-3-glycidoxypropylmethylsilane, N-(3-diethoxymethylsilylpropyl)succinimide, N-[3-(triethoxysilyl)propyl]phthalamic acid, benzophenone-3,3′-bis(N-[3-triethoxysilyl]propylamide)-4,4′-dicarboxylic acid, benzene-1,4-bis(N-[3-triethoxysilyl]propylamide)-2,5-dicarboxylic acid, 3-(triethoxysilyl)propylsuccinic anhydride, and N-phenylaminopropyltrimethoxysilane.

Examples of the aluminum-based adhesion promoter include aluminum tris(ethylacetoacetate), aluminum tris(acetylacetonate), and ethylacetoacetate aluminum diisopropylate.

The content of the adhesion promoter may be, for example, 0.5 mass % or more and 25 mass % or less, based on the total amount of the maleimide compound and the allyl compound.

The curable maleimide resin composition may further include a polymerization inhibitor. Examples of the polymerization inhibitor include hydroquinone, N-nitrosodiphenylamine, p-tert-butylcatechol, 4-methoxyphenol, phenothiazine, N-phenylnaphthylamine, ethylenediaminetetraacetic acid, 1,2-cyclohexanediaminetetraacetic acid, glycol ether diaminetetraacetic acid, 2,6-di-tert-butyl-p-methylphenol, 5-nitroso-8-hydroxyquinoline, 1-nitroso-2-naphthol, 2-nitroso-1-naphthol, 2-nitroso-5-(N-ethyl-N-sulfopropylamino) phenol, N-nitroso-N-phenylhydroxylamine ammonium salt, and N-nitroso-N(1-naphthyl) hydroxylamine ammonium salt.

The content of the polymerization inhibitor may be 0.005 mass % or more and 12 mass % or less, based on the total amount of the maleimide compound and the allyl compound.

The curable maleimide resin composition may further include an azole compound. Examples of the azole compound include 1H-triazole, 5-methyl-1H-triazole, 5-ethyl-1H-triazole, 4,5-dimethyl-1H-triazole, 5-phenyl-1H-triazole, 4-t-butyl-5-phenyl-1H-triazole, 5-hydroxyphenyl-1H-triazole, phenyltriazole, p-ethoxyphenyltriazole, 5-phenyl-1-(2-dimethylaminoethyl)triazole, 5-benzyl-1H-triazole, hydroxyphenyltriazole, 1,5-dimethyltriazole, 4,5-diethyl-1H-triazole, 1H-benzotriazole, 2-(5-methyl-2-hydroxyphenyl)benzotriazole, 2-[2-hydroxy-3,5-bis(a,a-dimethylbenzyl)phenyl]-benzotriazole, 2-(3,5-di-t-butyl-2-hydroxyphenyl)benzotriazole, 2-(3-t-butyl-5-methyl-2-hydroxyphenyl)-benzotriazole, 2-(3,5-di-t-amyl-2-hydroxyphenyl)benzotriazole, 2-(2′-hydroxy-5′-t-octylphenyl)benzotriazole, hydroxyphenylbenzotriazole, tolyltriazole, 5-methyl-1H-benzotriazole, 4-methyl-1H-benzotriazole, 4-carboxy-1H-benzotriazole, 5-carboxy-1H-benzotriazole, 1H-tetrazole, 5-methyl-1H-tetrazole, 5-phenyl-1H-tetrazole, 5-amino-1H-tetrazole, and 1-methyl-1H-tetrazole.

The content of the azole compound may be 0.1 mass % or more and 20 mass % or less, or 0.5 mass % or more and 5 mass % or less, based on the total amount of the maleimide compound and the allyl compound.

The curable maleimide resin composition may include a hindered phenol compound. Examples of the hindered phenol compound include 2,6-di-t-butyl-4-methylphenol, 2,5-di-t-butyl-hydroquinone, octadecyl-3-(3,5-di-t-butyl-4-hydroxyphenyl)propionate, isooctyl-3-(3,5-di-t-butyl-4-hydroxyphenyl)propionate, 4,4′-methylenebis(2,6-di-t-butylphenol), 4,4′-thio-bis(3-methyl-6-t-butylphenol), 4,4′-butylidene-bis(3-methyl-6-t-butylphenol), triethylene glycol-bis [3-(3-t-butyl-5-methyl-4-hydroxyphenyl)propionate], 1,6-hexanediol-bis [3-(3,5-di-t-butyl-4-hydroxyphenyl)propionate], 2,2-thio-diethylenebis [3-(3,5-di-t-butyl-4-hydroxyphenyl)propionate], N,N′-hexamethylenebis(3,5-di-t-butyl-4-hydroxy-hydrocinnamamide), 2,2′-methylene-bis(4-methyl-6-t-butylphenol), 2,2′-methylene-bis(4-ethyl-6-t-butylphenol), pentaerythrityl-tetrakis[3-(3,5-di-t-butyl-4-hydroxyphenyl)propionate], tris-(3,5-di-t-butyl-4-hydroxybenzyl)-isocyanurate, 1,3,5-trimethyl-2,4,6-tris(3,5-di-t-butyl-4-hydroxybenzyl)benzene, 1,3,5-tris(3-hydroxy-2,6-dimethyl-4-isopropylbenzyl)-1,3,5-triazine-2,4,6-(1H,3H,5H)-trione, 1,3,5-tris(4-t-butyl-3-hydroxy-2,6-dimethylbenzyl)-1,3,5-triazine-2,4,6-(1H,3H,5H)-trione, 1,3,5-tris(4-s-butyl-3-hydroxy-2,6-dimethylbenzyl)-1,3,5-triazine-2,4,6-(1H,3H,5H)-trione, 1,3,5-tris[4-(1-ethylpropyl)-3-hydroxy-2,6-dimethylbenzyl]-1,3,5-triazine-2,4,6-(1H,3H,5H)-trione, 1,3,5-tris[4-triethylmethyl-3-hydroxy-2,6-dimethylbenzyl]-1,3,5-triazine-2,4,6-(1H,3H,5H)-trione, 1,3,5-tris(3-hydroxy-2,6-dimethyl-4-phenylbenzyl)-1,3,5-triazine-2,4,6-(1H,3H,5H)-trione, 1,3,5-tris(4-t-butyl-3-hydroxy-2,5,6-trimethylbenzyl)-1,3,5-triazine-2,4,6-(1H,3H,5H)-trione, 1,3,5-tris(4-t-butyl-5-ethyl-3-hydroxy-2,6-dimethylbenzyl)-1,3,5-triazine-2,4,6-(1H,3H,5H)-trione, 1,3,5-tris(4-t-butyl-6-ethyl-3-hydroxy-2-methylbenzyl)-1,3,5-triazine-2,4,6-(1H,3H,5H)-trione, 1,3,5-tris(4-t-butyl-6-ethyl-3-hydroxy-2,5-dimethylbenzyl)-1,3,5-triazine-2,4,6-(1H,3H,5H)-trione, 1,3,5-tris(4-t-butyl-5,6-diethyl-3-hydroxy-2-methylbenzyl)-1,3,5-triazine-2,4,6-(1H,3H,5H)-trione, 1,3,5-tris(4-t-butyl-3-hydroxy-2-methylbenzyl)-1,3,5-triazine-2,4,6-(1H,3H,5H)-trione, 1,3,5-tris(4-t-butyl-3-hydroxy-2,5-dimethylbenzyl)-1,3,5-triazine-2,4,6-(1H,3H,5H)-trione, and 1,3,5-tris(4-t-butyl-5-ethyl-3-hydroxy-2-methylbenzyl)-1,3,5-triazine-2,4,6-(1H,3H,5H)-trione.

The content of the hindered phenol compound may be 0.1 mass % or more and 20 mass % or less, or 0.5 mass % or more and 10 mass % or less, based on the total amount of the maleimide compound and the allyl compound.

The curable maleimide resin composition may include an organotitanium compound. The organotitanium compound may be, for example, a titanium chelate compound having two or more alkoxy groups, a tetraalkoxy titanium compound, a titanocene compound, a monoalkoxy titanium compound, a titanium oxide compound, a titanium tetraacetylacetonate compound, a titanate coupling agent, or a combination thereof.

Examples of the titanium chelate compound having two or more alkoxy groups include titanium bis(triethanolamine) diisopropoxide, titanium di(n-butoxide) bis(2,4-pentanedionate), titanium diisopropoxide bis(2,4-pentanedionate), titanium diisopropoxide bis(tetramethylheptanedionate), and bis(ethylacetoacetate).

Examples of the tetraalkoxy titanium compound include titanium tetra(n-butoxide), titanium tetraethoxide, titanium tetra(2-ethylhexoxide), titanium tetraisobutoxide, titanium tetraisopropoxide, titanium tetramethoxide, titanium tetramethoxypropoxide, titanium tetramethylphenoxide, titanium tetra(n-nonyl oxide), titanium tetra(n-propoxide), titanium tetrastearyloxide, and titanium tetrakis[bis {2,2-(allyloxymethyl)butoxide}].

Examples of the titanocene compound include pentamethylcyclopentadienyltitanium trimethoxide, bis(n5-2,4-cyclopentadien-1-yl)bis(2,6-difluorophenyl) titanium, and bis(n5-2,4-cyclopentadien-1-yl)bis(2,6-difluoro-3-(1H-pyrrol-1-yl)phenyl) titanium.

Examples of the monoalkoxy titanium compound include titanium tris(dioctylphosphate) isopropoxide, and titanium tris(dodecylbenzenesulfonate) isopropoxide.

Examples of the titanium oxide compound include titanium oxide bis(pentanedionate), titanium oxide bis(tetramethylheptanedionate), and phthalocyanine titanium oxide.

Examples of the titanium tetraacetylacetonate compound include titanium tetraacetylacetonate.

Examples of the titanate coupling agent include isopropyl tridodecylbenzenesulfonyl titanate.

The content of the organotitanium compound may be 0.05 mass % or more and 10 mass % or less, or 0.1 mass % or more and 2 mass % or less, based on the total amount of the maleimide compound and the allyl compound.

The organic insulating film including the cured product of the curable maleimide resin composition is formed by a method including: applying the curable maleimide resin composition containing, for example, a solvent onto the original substrate 21 or the first substrate before being singulated; optionally removing the solvent from the applied film of the curable maleimide resin composition to form a resin film; and curing the resin film by heating to form the organic insulating film including the cured product of the curable maleimide resin composition. The heating temperature for removing the solvent may be, for example, 60° C. or more and 150° C. or less. By heating the resin film, curing reactions such as an ene reaction between the maleimide group and the allyl group, a Diels-Alder reaction involving the addition of a maleimide group, and radical polymerization proceed to form a cured product. Since the curing reaction proceeds mainly by addition reactions, generation of volatile content due to elimination components is unlikely. In addition, since the curing reaction proceeds at a relatively low temperature, thermal damage to the semiconductor substrate and the like can be reduced. The heating temperature for curing the resin film may be, for example, 170° C. or more and 260° C. or less. The heating time for curing the resin film may be, for example, 60 minutes or more and 180 minutes or less.

Other examples of the resin containing an imide group that can be included in the organic insulating film include a polyimide resin, a polyamide-imide resin, and a bismaleimide resin. The polyimide resin can be, for example, a polymer including a constitutional unit (imide unit) represented by the following formula (1A). The polyamide-imide resin can be a polymer including a constitutional unit (imide unit) represented by the following formula (1B) or (1C). Alternatively, the resin containing an imide group may be a resin having an imide unit represented by formula (1A), (1B), or (1C), and a linear, branched, or cage-like polysiloxane bonded to the imide unit.

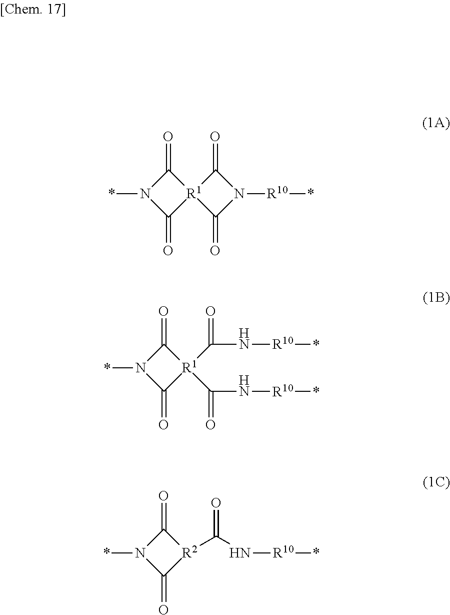

In formulas (1A) to (1C), R¹ represents a tetravalent organic group, R² represents a trivalent organic group, R¹⁰ represents a divalent organic group, and * represents a bonding hand.

R¹ can be a group including an aromatic group, and for example, R¹ may be a group resulting from removing four hydrogen atoms from a compound represented by the following formula (11), (12), or (13). R² can be a group including an aromatic group, and for example, R² may be a group resulting from removing three hydrogen atoms from a compound represented by the following formula (11), (12), or (13). In formula (13), X represents a direct bond, a methanediyl group, a propane-2,2-diyl group, a 1,1,1,3,3,3-hexafluoropropane-2,2-diyl group, a carbonyl group, a sulfonyl group, a thio group, a carbonyloxy group, an oxy group, a fluorene-9,9-diyl group, or an amide group.

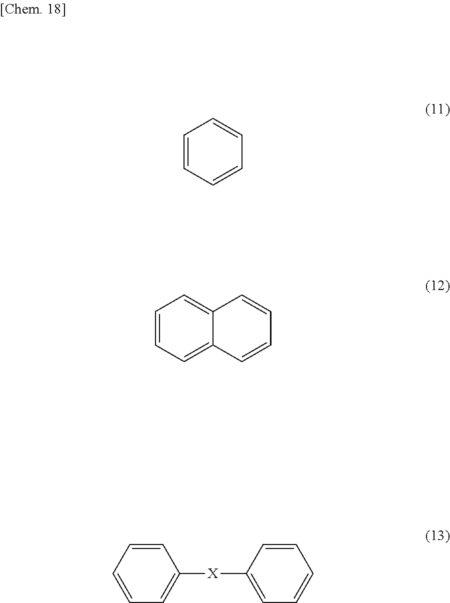

R¹⁰ in formulas (1A) to (1C) may be a group including a substituted or unsubstituted alkylene group, a group including a substituted or unsubstituted aromatic group, a group including a substituted or unsubstituted cycloaliphatic group, or a group including a combination thereof. The aromatic group may be a group resulting from removing two hydrogen atoms from a compound represented by formula (11), (12), or (13).

The organic insulating film including the resin containing an imide group can be formed by a method including applying a resin varnish containing a resin precursor onto a first semiconductor substrate or a second semiconductor substrate, and heating the coating film to form the organic insulating film including the resin containing an imide group. When forming an organic insulating film including a polymer containing imide units (polyimide resin or polyamide-imide resin), the resin precursor can be a polyamic acid having a constitutional unit corresponding to the imide unit. By heating the coating film, a curing reaction including an imidization reaction proceeds, whereby an organic insulating film including a polyimide resin or a polyamide-imide resin is formed. When forming an organic insulating film including a resin containing a polysiloxane bonded to an imide unit, the resin precursor can include a combination of a polycarboxylic acid compound corresponding to the imide unit and a polysiloxane substituted with a substituent having an amino group. The polycarboxylic acid compound may include an anhydride or a carboxylic acid ester. An organic insulating film including a resin having an imide group is formed by a curing reaction including a reaction between the amino group of the substituent bonded to the polysiloxane and the polycarboxylic acid compound, and an imidization reaction.

The organic insulating film may include a cured product of a curable resin composition containing an epoxy resin (curable epoxy resin composition). The curable epoxy resin composition can include, in addition to an epoxy resin which is a compound having two or more epoxy groups, any components such as a curing agent. The organic insulating film including the cured product of the curable epoxy resin composition can be formed in the same manner as the organic insulating film including the cured product of the curable maleimide resin composition, using a curable epoxy resin composition containing a solvent.

The organic insulating film may include a polybenzoxazole resin, a benzocyclobutene resin, or a combination thereof.

The organic insulating film including a polybenzoxazole resin can be formed by a method including applying a resin varnish containing a resin precursor onto a first semiconductor substrate or a second semiconductor substrate, and heating the coating film to cause a curing reaction including a reaction to form a benzoxazole group to proceed, thereby forming an insulating resin film including a polybenzoxazole resin.

### Verification Example

### (1) Preparation of Curable Resin Composition

The following maleimide compounds and allyl compounds were prepared. Maleimide compound
Phenylmethane maleimide (compound of formula 13, BMI-2300, Daiwa Kasei Kogyo Co., Ltd.)
4,4′-Diphenylmethane bismaleimide (compound of formula 14, BMI, Daiwa Kasei Kogyo Co., Ltd.)
   Allyl compound
Aryl phenol resin (compound of formula 23, LVA01, Gunei Chemical Industry Co., Ltd.)
2,2′-Diallyl bisphenol A (DABPA, Kanto Chemical Co., Inc.)
Compound of formula 25 (BATE, synthesized according to a conventional method)
Bisallyl nadimide (compound of formula 29, BANI-M, Maruzen Petrochemical Co., Ltd.)

### (2) Evaluation of Thermal Properties of Organic Insulating Film

A resin composition was prepared by mixing the maleimide compound and the allyl compound in the blending ratio (parts by mass) shown in Table 1 while melting them by heating. The resin composition was applied onto a substrate with a bar coater to form a resin film. The resin film was heated sequentially at 175° C. for 1 hour, 200° C. for 30 minutes, and 250° C. for 1 hour. The resin film was cured by this heating. By curing the resin film, an organic insulating film with a thickness of 100 μm was formed.

### Glass Transition Temperature (Tg)

The Tg of the organic insulating film was measured by dynamic mechanical analysis (DMA) under the following conditions. The temperature at which Tan & showed a maximum value was recorded as Tg.
Frequency: 10 Hz
Heating rate: 5° C./min

### Coefficient of Linear Thermal Expansion (CTE)

The coefficient of linear thermal expansion (CTE) of the organic insulating film was measured by the TMA method. The CTE in the temperature range of 50° C. to 100° C. was determined. The measurement results are shown in Table 1.

TABLE 1

| Example | | 1 | 2 | 3 | 4 |
|---|---|---|---|---|---|
| Maleimide | BMI-2300 | 50 | 51 | 53 | 54 |
| compound | | | | | |
| Allyl | LVA01 | 50 | 49 | 47 | 46 |
| compound | | | | | |

| | | | | |
|---|---|---|---|---|
| Tg(DMA)[C] | 320 | 348 | 350 | 350 |
| | or more | | or more | or more |
| CTE(TMA)[ppm/K] | 50 | 44 | 47 | — |

### (4) Bonding Test

### Test #1-1

The curable resin composition of Example 2 was applied onto a silicon wafer by a spin coater. The coating film was heated at 175° C. for 1 hour in a nitrogen atmosphere to form an organic insulating film (thickness 10 μm) including the cured product of the curable resin composition. The organic insulating film formed on the silicon wafer was polished by CMP. Subsequently, the silicon wafer was singulated together with the organic insulating film by blade dicing to obtain a lower test piece having a chip of 8 mm×8 mm size and an organic insulating film, and an upper test piece having a chip of 4 mm×4 mm size and an organic insulating film. The lower test piece was placed on a stage in an orientation such that the organic insulating film was positioned on top. The upper test piece, held by a preliminary thermocompression head in an orientation such that the chip was in contact with the preliminary thermocompression head, was thermocompression-bonded to the lower test piece on the stage for 10 seconds by the preliminary thermocompression head such that the organic insulating films were in contact with each other. During the thermocompression bonding, the pressure applied to the upper test piece by the preliminary thermocompression head was 0.5 MPa. The temperature of the preliminary thermocompression head was maintained at 130° C. from the start of holding the upper test piece until the end of the thermocompression bonding.

The preliminary thermocompression bonded body was heated and pressurized by a hot press set at a temperature of 250° C. with a pressure of 2.5 MPa for 5 minutes to obtain a bonded body for evaluation. A total of three bonded bodies for evaluation were produced under the same conditions.

### Test #2-1 and #3-1

Bonded bodies for evaluation were produced under the same conditions as in Test #1-1, except that the temperature of the preliminary thermocompression head was maintained at 150° C. or 200° C. from the start of holding the upper test piece until the end of the thermocompression bonding.

### Test #1-2, #2-2, #2-3

The temperature of the preliminary thermocompression head was set to 50° C. from the start of holding the upper test piece until the start of thermocompression bonding. From the time when the upper test piece and the lower test piece came into contact and thermocompression bonding started, the temperature of the preliminary thermocompression head was raised to 130° C., 150° C., or 200° C. over 3 seconds, held at that temperature for 10 seconds, and then lowered to 50° C. over 4 seconds. Otherwise, a total of three bonded bodies for evaluation were produced under the same conditions as in Test #1-1.

### Shear Test

The shear strength at 60° C. was measured by a peel test that applies stress along the bonding surface of the organic insulating film to the upper test piece of the bonded body. The shear strength of the preliminary thermocompression bonded bodies obtained under each temperature condition was also measured. The shear strength shown in Table 2 is the average of the values measured for three evaluation bonded bodies or preliminary thermocompression bonded bodies.

TABLE 2

| | | Preliminary | | Bonded |
|---|---|---|---|---|
| | Preliminary | thermocompression | Bonding/ | body |
| | thermocompression/ | bonded body | 2.5 MPa, | Shear |
| | 0.5 MPa, 10 s | Shear strength | 10 min | strength |
| | Temp. | [MPa] | Temp. | [MPa] |
| #1-1 | 130° C. (Constant) | 5.19 | 250° C. | 30.44 |
| #1-2 | 130° C. | 2.38 | 250° C. | 31.35 |
| | (Heating/Cooling) | | | |
| #2-1 | 150° C. (Constant) | 2.09 | 250° C. | 34.68 |
| #2-2 | 150° C. | 4.00 | 250° C. | 30.30 |
| | (Heating/Cooling) | | | |
| #3-1 | 200° C. (Constant) | 3.75 | 250° C. | 25.03 |
| #3-2 | 200° C. | 2.75 | 250° C. | 35.91 |
| | (Heating/Cooling) | | | |

The evaluation results are shown in Table 2. It was confirmed that under the condition where the temperature of the preliminary thermocompression head is maintained high, a bonded body in which the organic insulating films are sufficiently strongly bonded is efficiently formed.

### REFERENCE SIGNS LIST

10, 10A . . . first circuit member, 11, 11A . . . first substrate, 12 . . . first electrode, 13 . . . first insulating film, 13a . . . opening, 20A . . . second circuit member, 21 . . . original substrate, 21A . . . second substrate, 22 . . . second electrode, 23 . . . second insulating film, 23a . . . opening, 30 . . . preliminary thermocompression bonded body, 35 . . . bonded body, 35A . . . semiconductor device (bonded body), 40 . . . dicing tape, 50 . . . pickup tool, 65 . . . preliminary thermocompression head, 70 . . . stage, 80 . . . dicing tape, T₀ . . . initial temperature, T₁ . . . preliminary thermocompression temperature, Tₘᵢₙ . . . minimum temperature.

1. A method for manufacturing a semiconductor device, comprising:
preparing a first circuit member comprising a first substrate, a first electrode, and a first insulating film, the first electrode and the first insulating film being provided on the first substrate, the first insulating film forming an opening, and the first electrode being provided in the opening;
preparing a second circuit member comprising a second substrate, a second electrode, and a second insulating film, the second electrode and the second insulating film being provided on the second substrate, the second insulating film forming an opening, and the second electrode being provided in the opening;
disposing the first circuit member on a stage in an orientation such that the first substrate is positioned on the stage side;
holding the second circuit member on a preliminary thermocompression head in an orientation such that the second substrate is in contact with the preliminary thermocompression head;
thermocompression-bonding the second circuit member held on the preliminary thermocompression head to the first circuit member on the stage in an orientation such that the first electrode and the second electrode face each other, by the preliminary thermocompression head heated such that a maximum temperature of the preliminary thermocompression head is a preliminary thermocompression temperature, the preliminary thermocompression temperature being 250° C. or less, thereby forming a preliminary thermocompression bonded body comprising the first circuit member and the second circuit member; and
forming a bonded body comprising the first circuit member and the second circuit member, the first insulating film and the second insulating film being bonded together and the first electrode and the second electrode being bonded together, by pressurizing the preliminary thermocompression bonded body while heating to a bonding temperature equal to or higher than the preliminary thermocompression temperature,
wherein
at least one of the first substrate or the second substrate is a semiconductor substrate having a circuit surface,
when the first substrate is a semiconductor substrate having a circuit surface, the first electrode and the first insulating film are provided on the circuit surface, and when the second substrate is a semiconductor substrate having a circuit surface, the second electrode and the second insulating film are provided on the circuit surface,
at least one of the first insulating film or the second insulating film is an organic insulating film,
a plurality of the second circuit members are sequentially thermocompression-bonded to the first circuit member by the preliminary thermocompression head while maintaining a temperature of the preliminary thermocompression head within a range of a predetermined minimum temperature or more and the preliminary thermocompression temperature or less, and
the minimum temperature is a temperature of 70° C. or more and the preliminary thermocompression temperature or less.

2. The method according to claim 1, wherein the preliminary thermocompression temperature is 80° C. or more and 250° C. or less.

3. The method according to claim 1, wherein the preliminary thermocompression temperature is 100° C. or more and 250° C. or less.

4. The method according to claim 1, wherein the preliminary thermocompression temperature is 100° C. or more and 220° C. or less.

5. The method according to claim 1, wherein a difference between the preliminary thermocompression temperature and the minimum temperature is 20° C. or less.

6. The method according to claim 1, wherein a difference between the preliminary thermocompression temperature and the minimum temperature is 10° C. or less.

7. The method according to claim 1, wherein the bonding temperature is 200° C. or more and 350° C. or less.

8. The method according to claim 1, wherein the organic insulating film comprises a resin comprising an imide group.

9. The method according to claim 8, wherein the organic insulating film comprises a cured product of a curable resin composition comprising a maleimide compound having a maleimide group and an allyl compound having an allyl group.

10. The method according to claim 8, wherein the resin comprising an imide group is a polyimide resin, a polyamide-imide resin, a bismaleimide resin, or a combination thereof.

11. The method according to claim 8, wherein the resin comprising an imide group is a resin having a constitutional unit comprising an imide group, and a polysiloxane bonded to the constitutional unit.

12. The method according to claim 1, wherein the organic insulating film comprises a cured product of a curable resin composition comprising an epoxy resin.

13. The method according to claim 1, wherein the organic insulating film comprises a polybenzoxazole resin.

14. The method according to claim 1, wherein the organic insulating film comprises a benzocyclobutene resin.

15. A curable resin composition comprising a maleimide compound having a maleimide group, and an allyl compound having an allyl group, for use in forming an organic insulating film in the method according to claim 1.
